(19) United States
(12) Patent Application Publication
(10) Pub. No.: US 2013/0147024 A1
(43) Pub. Date: Jun. 13, 2013

(54) BALANCED LEADFRAME PACKAGE STRUCTURE AND METHOD OF MANUFACTURING THE SAME

(71) Applicants: Kim-Yong GOH, Singapore (SG); Xueren Zhang, Singapore (SG); Wingshenq Wong, Singapore (SG)

(72) Inventors: Kim-Yong GOH, Singapore (SG); Xueren Zhang, Singapore (SG); Wingshenq Wong, Singapore (SG)

(73) Assignee: STMicroelectronics PTE Ltd., Singapore (SG)

(21) Appl. No.: 13/324,799

(22) Filed: Dec. 13, 2011

(51) Int. Cl. H01L 23/495; H01L 21/50

(52) U.S. Cl. 257/676; 438/118; 438/123; 257/E23.031; 257/E21.499

(57) ABSTRACT

An integrated circuit package structure includes a bottom portion having a cavity, an integrated circuit attached to a top surface of the stepped cavity, a leadframe attached to the bottom portion, wire bonding for electrically coupling the integrated circuit to the leadframe, and a top portion conformally covering the integrated circuit and the bottom portion.

### BACKGROUND OF THE INVENTION

1. Field of the Invention

The present invention relates to integrated circuit packages and more particularly to a balanced leadframe package structure and a method of manufacturing the same.

2. Relevant Background

A typical integrated circuit package is shown below with respect to FIGS. 1-3. Further details of the integrated circuit package can be found in, for example, U.S. Pat. No. 7,449,369, although the package described below is well known in the art.

In pertinent part, FIGS. 1-3 illustrate the manufacture of an integrated circuit package 300. Referring now to FIG. 1, the bottom portion 306 of the package 300 includes a lead frame 312. Referring now to FIG. 2, an integrated circuit 302 is attached to the bottom portion 306 of the package 300 with adhesive 304, and coupled to the leadframe 312 via wire bonding 310. Referring now to FIG. 3, a top portion 308 is formed over the bottom portion 306, encapsulating the integrated circuit 302 and the wire bonding 310.

The integrated circuit package 300 is susceptible to undesired delamination at the “parting line” 314 between the top portion 308 and bottom portion 306. What is desired is an integrated circuit package that includes all of the known advantages of a classic integrated circuit package, yet overcomes the tendency towards delamination.

### SUMMARY OF THE INVENTION

The present invention seeks to solve package-level reliability issues due to unbalancing in the package structure. Any risk of package delamination in the die-pad interface is eliminated, since there is no existence of a die-pad in the integrated circuit package structure of the present invention. By a novel method of manufacturing, a leadframe package according to the present invention includes a well-balanced structure without a die-pad. The present invention thus comprises a balanced leadframe package structure for robust package-level reliability. Any risk of package delamination in the die-pad interface is substantially eliminated, since there is no existence of a die-pad in the integrated package structure of the present invention. There are thus no assembly or reliability issues related to die-pad shift or tilt (resulting in die shift or tilt) for the integrated circuit package of the present invention.

The balanced package structure of the present invention is achieved by creating a center cavity in the bottom mold of the integrated circuit package. The cavity height is designed such that the die is positioned in the center of the package when mounted. The balanced structure of the present invention has near-zero warpage during temperature excursions, and therefore the packaged integrated circuit is subjected to minimum thermo-mechanical stress, and superior package-level reliability is expected. In the prior art integrated circuit package, it is impossible to achieve this balance due to the packaging design and method of manufacturing.

Comparing the integrated circuit package of the present invention to that of the prior art, the “parting-line” between the top and bottom portions of the package are differentiated. The package of the present invention has a “step-wise” parting-line, while in the prior art, this parting-line is straight. As such, the package of the present invention has better mechanical inter-locking strength between the top and bottom portions. This “step-wise” parting-line provides needed structural integrity for processes such as “forming”, which may have the effect of tearing or shearing the top and bottom portions apart.

A first embodiment of an integrated circuit package structure according to the present invention includes a bottom portion having a stepped cavity, an integrated circuit attached to a top surface of the stepped cavity, a leadframe attached to the bottom portion, wire bonding for electrically coupling the integrated circuit to the leadframe, and a top portion conformally covering the integrated circuit and the bottom portion. A distance between a bottom surface of the integrated circuit and a bottom surface of the bottom portion is substantially equal to a distance between a top surface of the integrated circuit and a top surface of the of the top portion. A distance between a bottom surface of the bottom portion and a bottom surface of the leadframe is substantially equal to a distance between a top surface of the leadframe and a top surface of the of the top portion. The integrated circuit is centrally located in the stepped cavity. The top portion and the bottom portion each comprise a molding compound.

The method of forming the first embodiment of the integrated circuit package structure includes forming a bottom portion having a stepped cavity, attaching an integrated circuit to a top surface of the stepped cavity, attaching a leadframe to the bottom portion, electrically coupling the integrated circuit to the leadframe, and conformally covering the integrated circuit and the bottom portion with a top portion. The top portion and the bottom portion are formed using transfer molding.

A second embodiment of an integrated circuit package structure according to the present invention includes a bottom portion having a cavity with sloped edges, an integrated circuit attached to a top surface of the cavity, a leadframe attached to the bottom portion, wire bonding for electrically coupling the integrated circuit to the leadframe, and a top portion conformally covering the integrated circuit and the bottom portion. A distance between a bottom surface of the integrated circuit and a bottom surface of the bottom portion is substantially equal to a distance between a top surface of the integrated circuit and a top surface of the of the top portion. A distance between a bottom surface of the bottom portion and a bottom surface of the leadframe is substantially equal to a distance between a top surface of the leadframe and a top surface of the top portion. The integrated circuit is centrally located in the cavity. The top portion and the bottom portion each comprise a molding compound.

The method of forming the integrated circuit package structure includes forming a bottom portion having a cavity with sloped edges, attaching an integrated circuit to a top surface of the cavity, attaching a leadframe to the bottom portion, electrically coupling the integrated circuit to the leadframe, and conformally covering the integrated circuit and the bottom portion with a top portion. The top portion and the bottom portion are formed using transfer molding.

### BRIEF DESCRIPTION OF THE DRAWINGS

FIG. 1 is a cross-sectional view of the bottom portion of an integrated circuit package according to the prior art;

FIG. 2 is a cross-sectional view of the bottom portion of the integrated circuit package shown in FIG. 1, including an attached integrated circuit;

FIG. 3 is a cross-sectional view of the integrated circuit package shown in FIG. 1, including the top portion thereof;

FIG. 4 is a cross-sectional view of a first embodiment of an integrated circuit package according to the present invention;

FIGS. 5-9 are sequential cross-sectional views of the manufacturing process associated with the integrated circuit package of the present invention; and

FIG. 10 is a cross-sectional view of a second embodiment of an integrated circuit package according to the present invention.

### DETAILED DESCRIPTION OF THE PREFERRED EMBODIMENTS

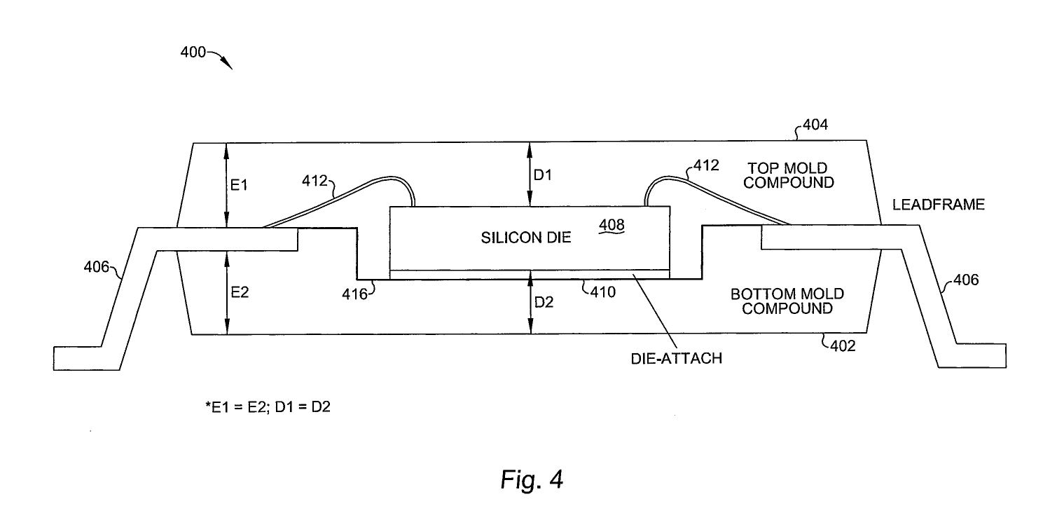

Referring now to FIG. 4, a first embodiment of an integrated circuit package structure 400 according to the present invention includes a bottom portion 402 having a stepped cavity, an integrated circuit 408 attached to a top surface of the stepped cavity with an adhesive 410 or other die-attach mechanism, a leadframe 406 attached to the bottom portion, wire bonding 412 for electrically coupling the integrated circuit to the leadframe, and a top portion 404 conformally covering the integrated circuit and the bottom portion. A distance D2 between a bottom surface of the integrated circuit 408 and a bottom surface of the bottom portion 402 is substantially equal to a distance D1 between a top surface of the integrated circuit 408 and a top surface of the of the top portion 404. A distance E2 between a bottom surface of the bottom portion 402 and a bottom surface of the leadframe 406 is substantially equal to a distance El between a top surface of the leadframe 406 and a top surface of the of the top portion 404. The integrated circuit 408 is centrally located in the stepped cavity. The top portion and the bottom portion each comprise a molding compound.

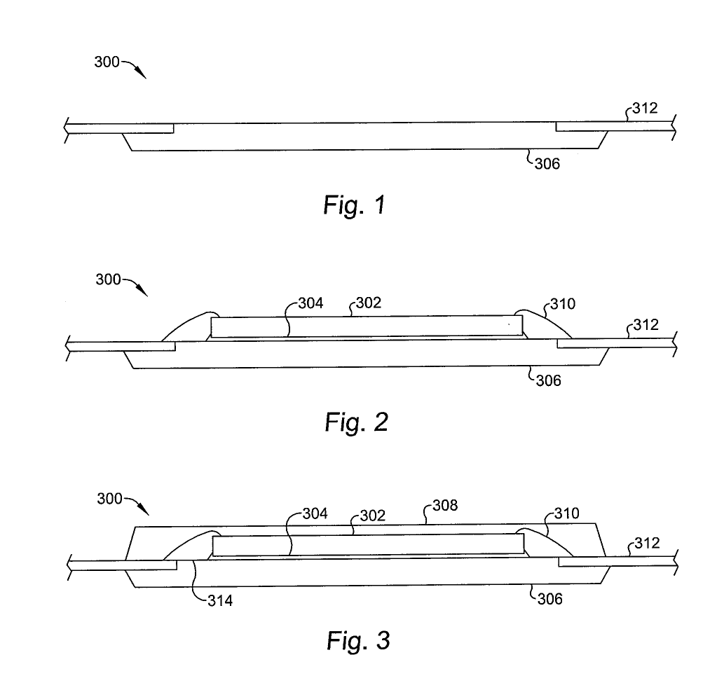

Note that the “parting-line” 416 between the top and bottom portion of the integrated circuit package 400 is stepped on either side of the integrated circuit 408, whereas the parting line 314 of the prior art package 300 shown in FIG. 1, it was a continuous straight line.

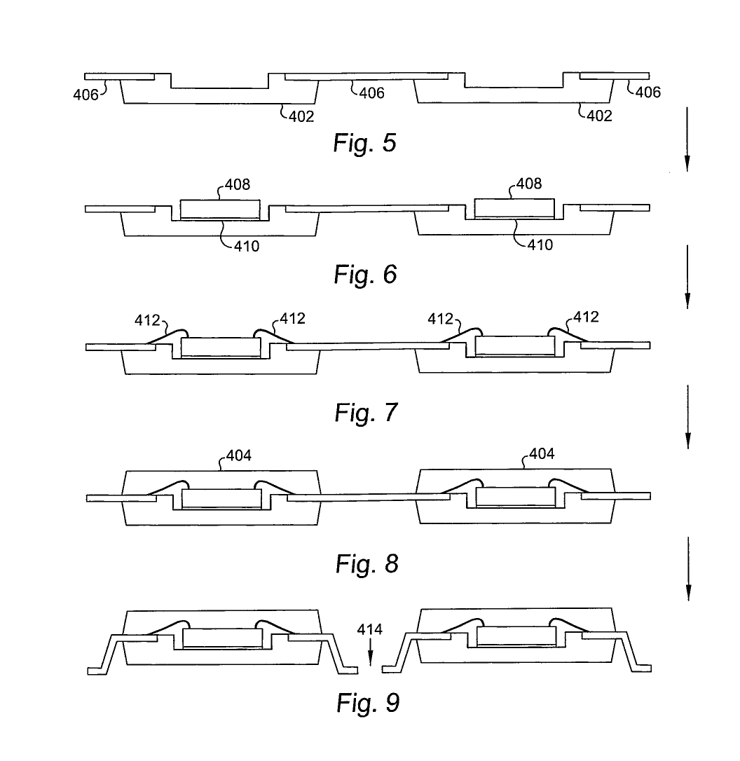

Referring now to FIGS. 5-9, the manufacturing sequence of the integrated circuit package is shown.

FIG. 5 shows the bottom cavity transfer molding with the stepped cavity insert of the bottom portion 402, and including the untrimmed leadframe 406. Note that two packages are shown. Manufacturing details can be changed to accommodate additional packages if desired. Once this step is complete it is followed by a Post Mold Cure (PMC) as is known in the art.

FIG. 6 shows the die-attach step of attaching the integrated circuit 408 to the bottom portion 402 of the package using adhesive or other known methods of die-attach.

FIG. 7 shows the wire-boding step, wherein wires are used to electrically couple the integrated circuit 408 to the untrimmed leadframe 406.

FIG. 8 shows the top cavity transfer molding of the top portion 404 of the integrated circuit package, which conformally covers the integrated circuit 408, the wire bonding 412, and the top surface of the bottom portion 402 of the integrated circuit package. Once the package 400 is fully formed, it is again subjected to a PMC.

FIG. 9 shows the final production steps, which include plating of the leadframe 406, trimming and forming the leadframe, and singulation 414 of the individual packages 400.

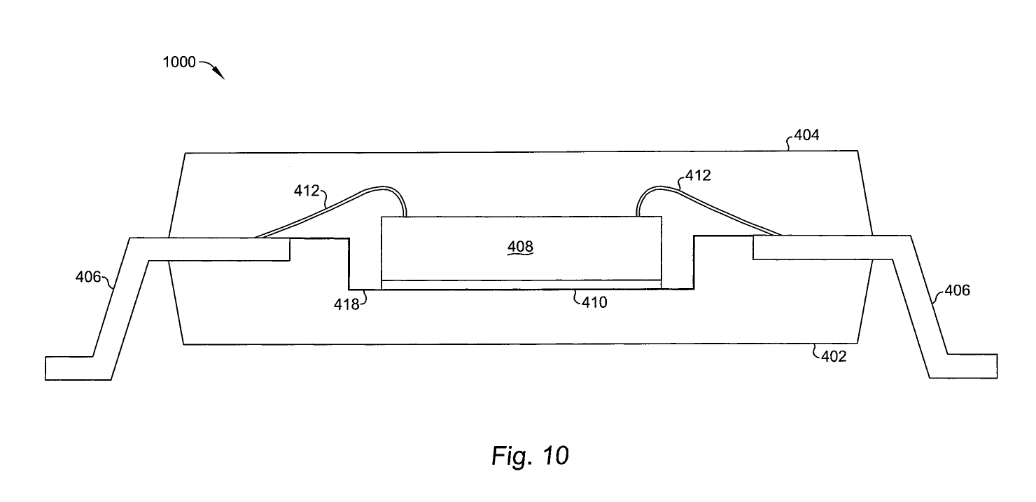

An additional embodiment of the invention is shown in FIG. 10. Package 1000 shows that the design of the parting-line is not limited to a step-wise embodiment as shown in FIG. 4. Other predetermined variations of the parting-line can be envisioned, such as the form that is shown in package 1000 of FIG. 10. In FIG. 10, the walls of the center cavity in the bottom mold (parting line 418) are linearly sloped at an angle to aid in mold release and avoid air-trap during molding.

An additional embodiment of the integrated circuit package structure 1000 includes a bottom portion 402 having a cavity with sloped edges, an integrated circuit 408 attached to a top surface of the cavity with an adhesive 410 or other die-attach, a leadframe 406 attached to the bottom portion, wire bonding 412 for electrically coupling the integrated circuit to the leadframe, and a top portion 404 conformally covering the integrated circuit and the bottom portion.

The method of manufacturing package 1000 proceeds essentially the same as that described above with respect to FIGS. 5-9.

While a stepped and linearly sloped bottom portion cavity is shown and described, it will be apparent to those skilled in the art that other types of cavities having predetermined profiles can be formed therein as desired, or to accommodate a particular manufacturing process.

It will be apparent to those skilled in the art, therefore, that various modifications and variations can be made to the invention without departing from the spirit or scope of the invention. Thus, it is intended that the present invention covers the modifications and variations of this invention provided they come within the scope of the appended claims and their equivalents.

We claim:

1. An integrated circuit package structure comprising:
a bottom portion having a cavity;
an integrated circuit attached to a top surface of the stepped cavity;
a leadframe attached to the bottom portion;
wire bonding for electrically coupling the integrated circuit to the leadframe; and
a top portion conformally covering the integrated circuit and the bottom portion.

2. The integrated circuit package structure of claim 1 wherein the cavity comprises a stepped cavity.

3. The integrated circuit package structure of claim 1 wherein the cavity comprises a cavity having sloped edges.

4. The integrated circuit package structure of claim 1 wherein the cavity comprises a predetermined profile.

5. The integrated circuit package structure of claim 1 wherein the bottom portion is molded to the leadframe.

6. The integrated circuit package structure of claim 1 wherein a distance between a bottom surface of the integrated circuit and a bottom surface of the bottom portion is substantially equal to a distance between a top surface of the integrated circuit and a top surface of the of the top portion.

7. The integrated circuit package structure of claim 1 wherein a distance between a bottom surface of the bottom portion and a bottom surface of the leadframe is substantially equal to a distance between a top surface of the leadframe and a top surface of the of the top portion.

8. The integrated circuit package structure of claim 1 wherein the integrated circuit is centrally located in the stepped cavity.

9. The integrated circuit package structure of claim 1 wherein the top portion and the bottom portion each comprise a molding compound.

10. The integrated circuit package structure of claim 1 wherein the integrated circuit is attached to the bottom portion with an adhesive.

11. A method of forming an integrated circuit package structure comprising:
forming a bottom portion having a cavity;
attaching an integrated circuit to a top surface of the stepped cavity;
attaching a leadframe to the bottom portion;
electrically coupling the integrated circuit to the leadframe; and
conformally covering the integrated circuit and the bottom portion with a top portion.

12. The method of claim 11 wherein the cavity comprises a stepped cavity.

13. The method of claim 11 wherein the cavity comprises a cavity having sloped edges.

14. The method of claim 11 wherein the cavity comprises a predetermined profile.

15. The method of claim 11 wherein the bottom portion is molded to the leadframe.

16. The method of claim 11 wherein a distance between a bottom surface of the integrated circuit and a bottom surface of the bottom portion is made substantially equal to a distance between a top surface of the integrated circuit and a top surface of the of the top portion.

17. The method of claim 11 wherein a distance between a bottom surface of the bottom portion and a bottom surface of the leadframe is made substantially equal to a distance between a top surface of the leadframe and a top surface of the of the top portion.

18. The method of claim 11 further comprising centrally locating the integrated circuit in the cavity.

19. The method of claim 11 wherein the top portion and the bottom portion are formed using transfer molding.

20. The method of claim 11 further comprising attaching the integrated circuit to the bottom portion with an adhesive.
